(19) United States
(12) Patent Application Publication
(10) Pub. No.: US 2025/0048636 A1
(43) Pub. Date: Feb. 6, 2025

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Bumkyu Kang, Suwon-si (KR); Jiyoung Kim, Suwon-si (KR); Sukkang Sung, Suwon-si (KR)

(21) Appl. No.: 18/652,120

(22) Filed: May 1, 2024

(30) Foreign Application Priority Data
Aug. 1, 2023 (KR) 10-2023-0100461

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A semiconductor device includes a first semiconductor structure including a substrate, circuit elements, and circuit interconnection lines, and a second semiconductor structure on the first semiconductor structure. The second semiconductor structure includes a plate layer, first gate electrodes stacked on the plate layer and spaced apart from each other in a first direction, separation regions penetrating through the first gate electrodes and extending in a second direction, first channel structures spaced apart from the separation regions in a third direction, penetrating through the first gate electrodes, and extending in the first direction, and dummy structures contacting the separation regions, penetrating through the first gate electrodes, and extending in the first direction. The first channel structures and the dummy structures respectively have a circular shape in plan view, and the separation regions are in contact with at least portions of respective side surfaces of the dummy structures.

### CROSS-REFERENCE TO RELATED APPLICATION(S)

This application claims priority to and the benefit of Korean Patent Application No. 10-2023-0100461, filed in the Korean Intellectual Property Office on Aug. 1, 2023, the disclosure of which is incorporated herein by reference in its entirety.

### BACKGROUND

In data storage systems, semiconductor devices can be used to store high-capacity data. Accordingly, data storage capacity of semiconductor devices is desired to be increased. Methods for increasing data storage capacity of semiconductor devices includes three-dimensionally arranged memory cells rather than two-dimensionally arranged memory cells.

### SUMMARY

In general, in some aspects, the present disclosure is directed to a semiconductor device having improved design freedom and reduced process difficulty. In some aspects, the present disclosure is directed to a data storage system including a semiconductor device with improved design freedom and reduced process difficulty.

According to some aspects of the present disclosure, a semiconductor device includes a first semiconductor structure including a substrate, circuit elements on the substrate, and circuit interconnection lines on the circuit elements; and a second semiconductor structure on the first semiconductor structure. The second semiconductor structure includes a plate layer; first gate electrodes stacked on the plate layer and spaced apart from each other in a first direction, perpendicular to an upper surface of the plate layer; separation regions penetrating through the first gate electrodes and extending in a second direction, perpendicular to the first direction; first channel structures spaced apart from the separation regions in a third direction, perpendicular to the first direction and the second direction, penetrating through the first gate electrodes, and extending in the first direction; and dummy structures contacting the separation regions, penetrating through the first gate electrodes, and extending in the first direction. The first channel structures and the dummy structures respectively have a circular shape in plan view, and the separation regions are in contact with at least portions of respective side surfaces of the dummy structures.

According to some aspects of the present disclosure, a semiconductor device includes a plate layer; gate electrodes stacked on the plate layer and spaced apart from each other in a first direction, perpendicular to an upper surface of the plate layer; channel structures penetrating through the gate electrodes, extending in the first direction, and arranged in rows along a second direction, perpendicular to the first direction; dummy structures on outsides of the channel structures, extending in the first direction, penetrating through the gate electrodes, and arranged in rows along the second direction; and separation regions between the rows of the dummy structures, penetrating through the gate electrodes, and extending in the second direction. The channel structures are arranged at a first pitch in a third direction, perpendicular to the first direction and the second direction, and a width of the separation regions is greater than the first pitch.

According to some aspects of the present disclosure, a data storage system includes a semiconductor storage device including a first semiconductor structure including circuit elements, a second semiconductor structure on one surface of the first semiconductor structure, and an input/output pad electrically connected to the circuit elements; and a controller electrically connected to the semiconductor storage device through the input/output pad and configured to control the semiconductor storage device. The second semiconductor structure includes a plate layer; gate electrodes stacked on the plate layer and spaced apart from each other in a first direction, perpendicular to an upper surface of the plate layer; channel structures extending in the first direction, penetrating through the gate electrodes, and arranged in rows along a second direction, perpendicular to the first direction; dummy structures on outsides of the channel structures, penetrating through the gate electrodes, extending in the first direction, and arranged in rows along the second direction; and separation regions between the rows of the dummy structures, penetrating through the gate electrodes, and extending in the second direction. The separation regions surround at least a portion of each of the dummy structures and are in contact with the dummy structures.

### BRIEF DESCRIPTION OF DRAWINGS

Exemplary implementations will be more clearly understood from the following detailed description, taken in conjunctions with the accompanying drawings.

FIG. 1 is a schematic plan view of an exemplary semiconductor device according to some implementations.

FIG. 2 is a schematic cross-sectional view of an exemplary semiconductor device according to some implementations.

FIGS. 3A and 3B are schematic partially enlarged views of an exemplary semiconductor device according to some implementations.

FIGS. 4A and 4B are schematic plan views of an exemplary semiconductor device according to some implementations.

FIG. 5 is a schematic cross-sectional view of an exemplary semiconductor device according to some implementations.

FIGS. 6A to 6C are schematic cross-sectional views of an exemplary semiconductor device according to some implementations.

FIG. 7 is a schematic cross-sectional view of an exemplary semiconductor device according to some implementations.

FIGS. 8 to 17 are schematic cross-sectional views illustrating an exemplary method of manufacturing a semiconductor device according to some implementations.

FIG. 18 is a diagram schematically illustrating an exemplary data storage system including a semiconductor device according to some implementations.

FIG. 19 is a perspective view schematically illustrating an exemplary data storage system including a semiconductor device according to some implementations.

FIG. 20 is a cross-sectional view schematically illustrating an exemplary semiconductor package according to some implementations.

### DETAILED DESCRIPTION

Hereinafter, exemplary implementations will be described in detail with reference to the accompanying drawings.

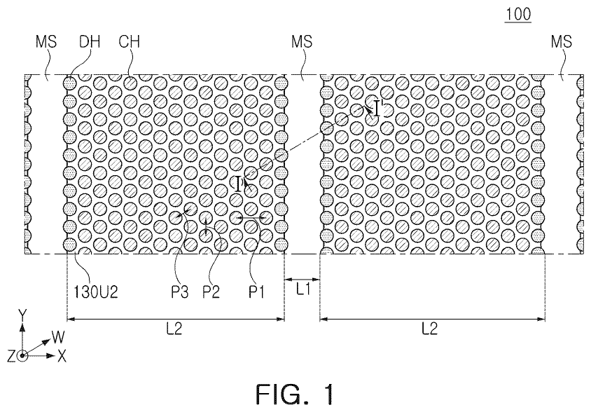

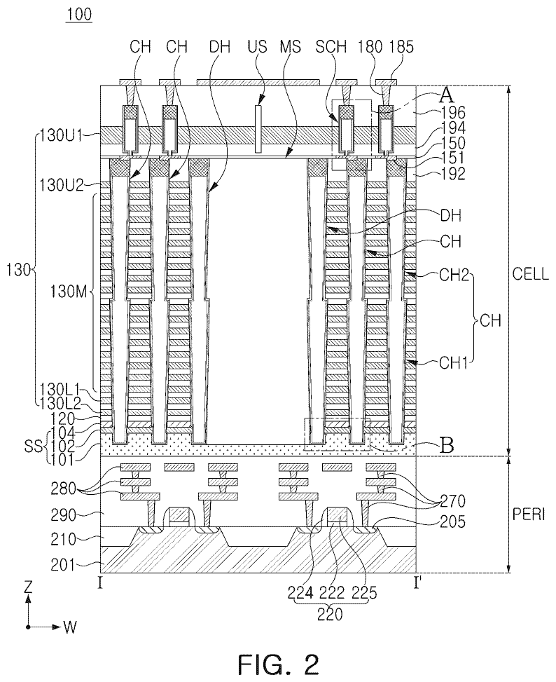

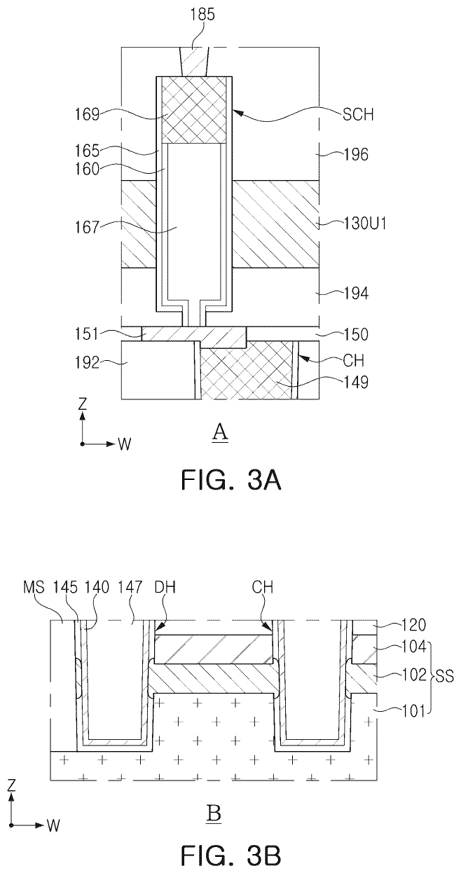

FIG. 1 is a schematic plan view of an exemplary semiconductor device according to some implementations, including an arrangement of components below a level of upper surfaces of first channel structures CH. FIG. 2 is a schematic cross-sectional view along section I-I′ in FIG. 1 of an exemplary semiconductor device according to some implementations. FIGS. 3A and 3B are schematic partially enlarged views of an exemplary semiconductor device according to some implementations, in which FIG. 3A illustrates an enlarged view of the ‘A’ area of FIG. 2, and FIG. 3B illustrates an enlarged view of the ‘B’ area of FIG. 2.

In FIGS. 1, 2, 3A, and 3B, a semiconductor device 100 may include a peripheral circuit area PERI, which is a first semiconductor structure including a substrate 201, and a memory cell region CELL, which is a second semiconductor structure including a plate layer 101. In some implementations, the memory cell area CELL may be disposed on the peripheral circuit area PERI. In some implementations, the memory cell area CELL may be disposed below the peripheral circuit area PERI.

The peripheral circuit area PERI may include a substrate 201, impurity regions 205 and device isolation layers 210 within the substrate 201, circuit elements 220 disposed on the substrate 201, a peripheral region insulating layer 290, and a circuit contact. The peripheral circuit area PERI also includes plugs 270 and circuit interconnection lines 280.

The substrate 201 may have an upper surface extending in the X-direction and Y-direction. An active area may be defined on the substrate 201 by the device isolation layers 210, and impurity regions 205 containing impurities may be disposed in a portion of the active region. The substrate 201 may include a semiconductor material, such as a group IV semiconductor, a group III-V compound semiconductor, or a group II-VI compound semiconductor. In some implementations, the substrate 201 may be provided as a bulk wafer or an epitaxial layer.

The circuit elements 220 may include planar transistors, in which each circuit element 220 may include a circuit gate dielectric layer 222, a spacer layer 224, and a circuit gate electrode 225. The impurity regions 205 may be disposed as source/drain regions in the substrate 201 on both sides of the circuit gate electrode 225.

The peripheral area insulating layer 290 may be disposed on the circuit element 220 on the substrate 201 and may include a plurality of insulating layers formed in different process steps. The peripheral area insulating layer 290 may be formed of an insulating material.

The circuit contact plugs 270 and the circuit interconnection lines 280 may form a circuit interconnection structure electrically connected to the circuit elements 220 and the impurity regions 205. In some implementations, the circuit contact plugs 270 may have a cylindrical shape, and the circuit interconnection lines 280 may have a line shape. An electrical signal may be applied to the circuit element 220 through the circuit contact plugs 270 and circuit interconnection lines 280. Although not illustrated, circuit contact plugs 270 may also be connected to the circuit gate electrode 225. The circuit interconnection lines 280 may have a linear shape, may be connected to circuit contact plugs 270, and may be disposed in multiple layers. The circuit contact plugs 270 and the circuit interconnection lines 280 may include a conductive material, for example, tungsten (W), copper (Cu), aluminum (Al), or the like. Respective components may further include a diffusion barrier. In some implementations, the number of layers of circuit contact plugs 270 and circuit interconnection lines 280 may vary.

The memory cell area CELL may include a source structure SS, gate electrodes 130 stacked on the source structure SS, and interlayer insulating layers 120 alternately stacked. The memory cell area CELL may further include first channel structures CH and second channel structures SCH disposed to penetrate the gate electrodes 130, first separation regions MS extending through portions of the gate electrodes 130, dummy structures DH disposed to contact the first separation regions MS and penetrate the gate electrodes 130, second separation regions US penetrating through the first upper gate electrode 130U1 among the gate electrodes 130, a horizontal insulating layer 150 disposed between the first channel structures CH and the second channel structures SCH, studs 180 on second channel structures SCH, and bit lines 185 on the studs 180. The memory cell region CELL may further include first to third cell region insulating layers 192, 194, and 196 on the gate electrodes 130.

The source structure SS may include a plate layer 101, a first horizontal conductive layer 102, and a second horizontal conductive layer 104 that are sequentially stacked. In some implementations, the number of conductive layers forming the source structure SS may vary.

The plate layer 101 has the shape of a plate and may function as at least part of the common source line of the semiconductor device 100. The plate layer 101 may have an upper surface extending in the X-direction and Y-direction and may include a conductive material. For example, the plate layer 101 may include a semiconductor material, such as a group IV semiconductor, a group III-V compound semiconductor, or a group II-VI compound semiconductor. For example, Group IV semiconductors may include silicon, germanium, or silicon-germanium. The plate layer 101 may further include impurities. The plate layer 101 may be provided as a polycrystalline semiconductor layer, such as a polycrystalline silicon layer, or an epitaxial layer.

The first and second horizontal conductive layers 102 and 104 may be sequentially stacked and disposed on the upper surface of the plate layer 101. The first horizontal conductive layer 102 may function as part of a common source line of the semiconductor device 100, and for example, may function as a common source line together with the plate layer 101. In FIG. 3B, the first horizontal conductive layer 102 may be directly connected to the first channel layer 140 around the first channel layer 140 of each of the first channel structures CH.

The first and second horizontal conductive layers 102 and 104 may include a semiconductor material, for example, polycrystalline silicon. Additionally, at least the first horizontal conductive layer 102 may be a layer doped with impurities of the same conductivity type as the plate layer 101, and the second horizontal conductive layer 104 may be a doped layer or a layer containing impurities diffused from the first horizontal conductive layer 102. However, the material of the second horizontal conductive layer 104 is not limited to semiconductor materials.

Portions of the gate electrodes 130, those excluding the first upper gate electrode 130U1, may be stacked to be vertically spaced apart on the plate layer 101 to form a stack structure together with the interlayer insulating layers 120. The stack structure may include vertically stacked lower and upper stack structures. However, in some implementations, the laminated structure may be composed of a single laminated structure.

The gate electrodes 130 may include a first upper gate electrode 130U1 forming string selection transistors, a second upper gate electrode 130U2 forming an erase transistor, memory gate electrodes 130M forming a plurality of memory cells, a first lower gate electrode 130L1 constituting an erase transistor, and a second lower gate electrode 130L2 constituting the ground selection transistor. The number of memory gate electrodes 130M constituting memory cells may be determined according to the capacity of the semiconductor device 100. In some implementations, the second upper gate electrode 130U2, the first lower gate electrode 130L1, and the second lower gate electrode 130L2 may be each 1 to 4, or more. In some implementations, the positions of the first lower gate electrode 130L1 and the second lower gate electrode 130L2 may be exchanged. In some implementations, the second upper gate electrode 130U2 and/or the first lower gate electrode 130L1 may be omitted. In some implementations, portions of the memory gate electrodes 130M may be dummy gate electrodes.

The second lower gate electrode 130L2, first lower gate electrode 130L1, memory gate electrodes 130M, and second upper gate electrode 130U2 disposed sequentially from the bottom may be referred to as first gate electrodes, and the first upper gate electrode 130U1 may be referred to as a second gate electrode. In some implementations, the thickness of the first upper gate electrode 130U1, for example, the second gate electrode, may be greater than the thickness of each of the first gate electrodes.

The gate electrodes 130 may include a conductive material, for example, at least one metallic substance among tungsten (W), molybdenum (Mo), tantalum (Ta), ruthenium (Ru), niobium (Nb), osmium (Os), zironium (Zr), iridium (Ir), rhenium (Re), and titanium (Ti), or a semiconductor material, such as polycrystalline silicon. For example, the first upper gate electrode 130U1 may include polycrystalline silicon, and the other gate electrodes 130 may include a metal material.

The interlayer insulating layers 120 may be disposed between the gate electrodes 130 excluding the first upper gate electrode 130U1. Like the gate electrodes 130, the interlayer insulating layers 120 may also be disposed to be spaced apart from each other in a direction perpendicular to the upper surface of the plate layer 101. The interlayer insulating layers 120 may include an insulating material, such as silicon oxide or silicon nitride. In example some implementations, the thickness of each of the interlayer insulating layers 120 may vary.

The first channel structures CH extend in the Z-direction through the gate electrodes 130, excluding the first upper gate electrode 130U1, and may be connected to the plate layer 101. The first channel structures CH, together with the second channel structures SCH, each form one memory cell string, and may be disposed to be spaced apart from each other in rows and columns on the plate layer 101. In FIG. 1, the first channel structures CH may be disposed to form a grid pattern together with the dummy structures DH in the X-Y plane or may be disposed in a zigzag shape in one direction. The first channel structures CH may be regularly arranged together with the dummy structures DH, and each of the first channel structures CH may have a pillar shape and may have inclined side surfaces that become narrower as they approach the plate layer 101.

The first channel structures CH may be disposed at a first pitch P1 in the X-direction, disposed at a second pitch P2 in the Y-direction, and disposed at a third pitch P3 in the W-direction inclined to the X- and Y-directions. In some implementations, the first pitch P1 may be larger than the second pitch P2 and the third pitch P3. However, at least portions of the first pitch P1, the second pitch P2, and the third pitch P3 may be the same or different from each other, and relative sizes thereof may vary in some implementations.

In FIGS. 3A and 3B, each of the first channel structures CH may include a first channel layer 140, a first gate dielectric layer 145, a first channel buried insulating layer 147, and a first channel pad 149 disposed in the lower channel hole. The first channel layer 140 may be formed in an annular shape surrounding the internal first channel buried insulating layer 147, and depending upon some implementations, may have a pillar shape, such as a cylinder or a prism, without the first channel buried insulating layer 147. The lower portion of the first channel layer 140 may be connected to the first horizontal conductive layer 102. The first channel layer 140 may include a semiconductor material, such as polycrystalline silicon or single crystalline silicon.

The first gate dielectric layer 145 may be disposed between the gate electrodes 130 and the first channel layer 140. Although not shown, the first gate dielectric layer 145 may include a tunneling layer, a data storage layer, and a blocking layer sequentially stacked from the first channel layer 140. The tunneling layer may tunnel charges into the data storage layer and may include, for example, silicon oxide (SiO₂), silicon nitride (Si₃N₄), silicon oxynitride (SiON), or combinations thereof. The data storage layer may be a charge trap layer or a floating gate conductive layer. The blocking layer may include silicon oxide (SiO₂), silicon nitride (Si₃N₄), silicon oxynitride (SiON), a high-k dielectric material, or combinations thereof. In some implementations, at least a portion of the first gate dielectric layer 145 may extend in a horizontal direction along the gate electrodes 130.

The first channel buried insulating layer 147 may include an insulating material, for example, silicon oxide, silicon nitride, or silicon oxynitride. The first channel pad 149 may be disposed only on the upper end of the upper channel structure CH2 provided thereabove. The first channel pad 149 may include, for example, doped polycrystalline silicon.

The first channel structures CH may include vertically stacked lower and upper channel structures CH1 and CH2. The first channel structures CH may have a shape in which lower channel structures CH1 and upper channel structures CH2 are connected, and the connection area may have a bend due to a difference in width. However, in some implementations, the number of channel structures stacked in the Z-direction may vary. The first channel layer 140, the first gate dielectric layer 145, and the first channel buried insulating layer 147 may continuously extend between the lower channel structure CH1 and the upper channel structure CH2.

The dummy structures DH extend in the Z-direction through the gate electrodes 130 excluding the first upper gate electrode 130U1 and may be connected to the plate layer 101. The dummy structures DH may be arranged in a certain pattern together with the first channel structures CH. The dummy structures DH may be disposed in a row outside the outermost rows of the first channel structures CH in the X-direction. The dummy structures DH may be disposed in rows on both sides of each of the first separation regions MS in the X-direction. The dummy structures DH may be disposed between the first channel structures CH and the first separation regions MS. A portion of each side surface of the dummy structures DH may contact the first separation regions MS.

Each of the dummy structures DH may have a circular shape, as shown in the plan view of FIG. 1, and each of the first channel structures CH may also have the same circular shape in a plan view. In some implementations, the dummy structures DH and the first channel structures CH may have a cylindrical shape of substantially the same size. In the plan view, the first separation regions MS may contact a portion of the circular side surface of each of the dummy structures DH.

The dummy structures DH may have the same internal structure as the first channel structures CH. Each of the dummy structures DH may include a first channel layer 140, a first gate dielectric layer 145, a first channel buried insulating layer 147, and a first channel pad 149 disposed in the lower channel hole. In each of the dummy structures DH, the shapes of the layers may be substantially the same as the shapes of the layers in each of the first channel structures CH.

However, unlike the first channel structures CH, the dummy structures DH may not form a memory cell string within the semiconductor device 100. The dummy structures DH may not be electrically connected to the cell interconnection structure. Accordingly, the second channel structures SCH may not be connected to the dummy structures DH, and all upper surfaces thereof may be covered with the horizontal insulating layer 150. In lower regions of the dummy structures DH, the first channel layer 140 may be connected to the first horizontal conductive layer 102. However, the detailed shape of the first horizontal conductive layer 102 in the regions where the dummy structures DH contact the first separation regions MS is not limited to that shown in FIG. 3B.

The second channel structures SCH extend in the Z-direction through the first upper gate electrode 130U1, and may be physically and electrically connected to the first channel structures CH, respectively. The second channel structures SCH may be respectively disposed on the first channel structures CH. In some implementations, at least portions of the second channel structures SCH are not aligned with the first channel structures CH, and may be shifted in the X-direction or placed misaligned. In some implementations, portions of the second channel structures SCH may have misaligned lengths that are different from those of the first channel structures CH. The diameter of the second channel structures SCH may be smaller than the diameter of the first channel structures CH, but is not limited thereto.

In FIG. 3A, each of the second channel structures SCH may include a second channel layer 160, a second gate dielectric layer 165, a second channel buried insulating layer 167, and a second channel pad 169 disposed in the upper channel hole. The second channel layer 160 may be formed in a ring shape surrounding the internal second channel buried insulating layer 167. The lower portion of the second channel layer 160 may be connected to the connection pad 151, and may be electrically connected to the first channel layer 140 of the first channel structure CH through the connection pad 151.

The second gate dielectric layer 165 may include silicon oxide (SiO₂), silicon nitride (Si₃N₄), silicon oxynitride (SiON), a high-k dielectric material, or combinations thereof. Regarding materials of the second channel layer 160, the second channel buried insulating layer 167, and the second channel pad 169, the above descriptions for the first channel layer 140, the first channel buried insulating layer 147, and the first channel pad 149 may be applied, respectively.

The horizontal insulating layer 150 may be disposed between the first channel structures CH and the second channel structures SCH and extend horizontally. The horizontal insulating layer 150 may be disposed between the first upper gate electrode 130U1 and the second upper gate electrode 130U2. The horizontal insulating layer 150 is used as an etch stop layer when forming the second channel structures SCH, and may also be a layer used when forming the connection pads 151.

The horizontal insulating layer 150 includes an insulating material and may include a material different from the second and third cell region insulating layers 194 and 196. The horizontal insulating layer 150 may include nitride, for example, at least one of SiN, SiON, SiCN, and SiOCN.

The connection pads 151 may penetrate the horizontal insulating layer 150 between the first channel structures CH and the second channel structures SCH, and the first channel layers 140 and the second channel layers 160 may be electrically connected. The connection pads 151 are formed by partially removing the horizontal insulating layer 150 and may have upper surfaces that are coplanar with the upper surface of the horizontal insulating layer 150. The connection pads 151 may be disposed in a partially recessed form of the first channel pads 149. However, the detailed arrangement of the connection pads 151 may vary in various implementations. The connection pads 151 may include a conductive material, for example, polycrystalline silicon. In some embodiments, the connection pads 151 may be integrated with the second channel layers 160.

The first separation regions MS may be disposed to extend in the Y-direction through the gate electrodes 130 except for the first upper gate electrode 130U1. In FIG. 1, the first separation regions MS may be disposed parallel to each other. The gate electrodes 130 separated by the first isolation regions MS may form one memory block. The range of the memory block is not limited thereto. In FIG. 2, the first separation regions MS penetrate the gate electrodes 130 stacked on the plate layer 101, and may further penetrate the first and second horizontal conductive layers 102 and 104 below and be connected to the plate layer 101.

The first separation regions MS may contact the dummy structures DH. For example, in some implementations, the first separation regions MS may be located between rows of dummy structures DH, and may be in contact with a portion of each of the dummy structures DH forming the rows. In FIG. 1, the first separation regions MS may surround a portion of each side surface of the dummy structures DH. In the plan view, portions of the side surfaces of the first separation regions MS are in contact with the dummy structures DH, and other portions thereof may be located between the dummy structures DH. The side surfaces of the first separation regions MS may have curves corresponding to the side surfaces of the dummy structures DH. Even in areas in which the first separation regions MS do not contact the dummy structures DH, and side surfaces of the first separation regions MS may have curves corresponding to the first channel structures CH and the dummy structures DH. In FIG. 2, the entire side surface of each of the dummy structures DH from top to bottom may be in contact with the first separation region MS in some regions.

The width L1 of the first separation regions MS in the X-direction may be greater than the first pitch P1 of the first channel structures CH in the X-direction. For example, the width L1 may be greater than the first pitch P1 and less than twice the first pitch P1. For example, the width L1 may range from about 400 nm to about 700 nm. In some implementations, the length L2 between adjacent first separation regions MS in the X-direction may be the same. The length L2 may correspond to the length of the memory block. The first separation regions MS may include an insulating material, for example, silicon oxide, silicon nitride, or silicon oxynitride.

In FIG. 2, the second separation region US may penetrate the first upper gate electrode 130U1 disposed at the top among the gate electrodes 130. The second separation regions US may extend in the Y-direction, and a plurality of second separation regions US may be disposed between adjacent first separation regions MS. The second separation regions US may divide the first upper gate electrode 130U1 into a plurality of parts between the first separation regions MS. The upper surfaces of the second separation regions US may be positioned at substantially the same level as the upper surfaces of the second channel structures SCH. The second isolation regions US may include an insulating material, for example, silicon oxide, silicon nitride, or silicon oxynitride.

The studs 180 may form a cell interconnection structure electrically connected to memory cells in the memory cell area CELL. The studs 180 are connected to the second channel structures SCH, and may be electrically connected to the first channel structures CH and the second channel structures SCH. The studs 180 have a hole shape and may be connected to the second channel pads 169 of the second channel structures SCH. The studs 180 may electrically connect the first channel structures CH and the second channel structures SCH to the bit lines 185. The bit lines 185 may be connected to the studs 180 and electrically connected to the first channel structures CH and the second channel structures SCH. The studs 180 and bit lines 185 may include metal, for example, tungsten (W), copper (Cu), aluminum (Al), or the like.

The first to third cell region insulating layers 192, 194, and 196 may be disposed on the gate electrodes 130. The first cell region insulating layer 192 covers the second upper gate electrode 130U2, the second cell region insulating layer 194 covers the horizontal insulating layer 150, and the third cell region insulating layer 196 may cover the first upper gate electrode 130U1. The first to third cell region insulating layers 192, 194, and 196 may be formed of an insulating material, and each may be formed of a plurality of insulating layers.

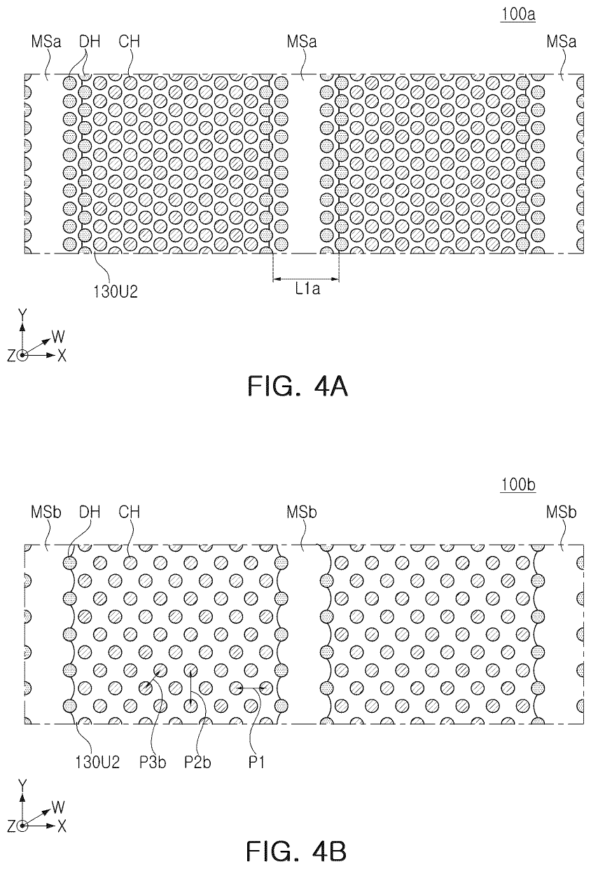

FIGS. 4A and 4B are schematic plan views of an exemplary semiconductor device according to some implementations, and illustrate areas corresponding to FIG. 1. In FIG. 4A, in the semiconductor device 100a, two rows of dummy structures DH may be disposed on one side of each of the first separation regions MSa in the X-direction. The first separation regions MSa completely surround the side surfaces of the first row of adjacent dummy structures DH, and may surround a portion of each side surface of the dummy structures DH in the second row. Accordingly, the first separation regions MSa may have a relatively increased width L1a. In some implementations, three or more rows of dummy structures DH may be disposed on one side of each of the first separation regions MSa in the X-direction.

In FIG. 4B, in the semiconductor device 100b, side surfaces of the first separation regions MSb may have a relatively more curved shape in regions extending between the dummy structures DH. For example, in some implementations, as compared to FIG. 1, the second pitch P2b in the Y-direction and the third pitch P3b in the W-direction of the first channel structures CH1 may be relatively large. Accordingly, the degree of curvature of the side surfaces of the first separation regions MSb may vary depending on the pitches at which the first channel structures CH1 and the dummy structures DH are arranged.

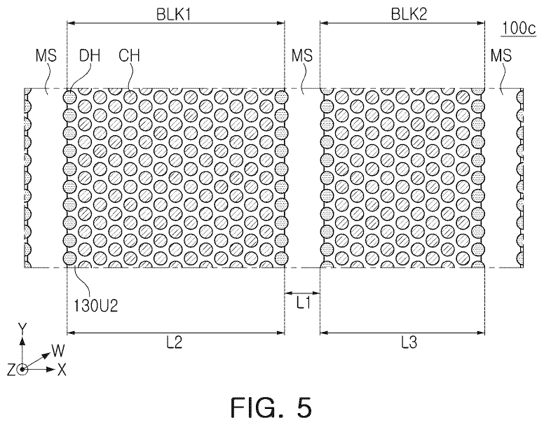

FIG. 5 is a schematic cross-sectional view of an exemplary semiconductor device according to some implementations. In FIG. 5, in the semiconductor device 100c, the first memory block BLK1 and the second memory block BLK2 defined by the first separation regions MS may have different lengths. The first memory block BLK1 and the second memory block BLK2 may be adjacent to or spaced apart from each other. For example, the first memory block BLK1 may be a main memory block, and the second memory block BLK2 may be a spare memory block. Accordingly, the first channel structures CH in the second memory block BLK2 may also be electrically connected to the second channel structures SCH, the studs 180, and the bit lines 185 described above with reference to FIGS. 1, 3A, and 3B.

The length L3 of the second memory block BLK2 may be smaller than the length L2 of the first memory block BLK1. The length L2 of the first memory block BLK1 corresponds to the length between the first separation regions MS on both sides of the first memory block BLK1, and the length L3 of the second memory block BLK2 may correspond to the length between the first separation regions MS on both sides of the second memory block BLK2.

Accordingly, the pitch between the first separation regions MS forming the second memory block BLK2 may be smaller than the pitch between the first separation regions MS forming the first memory block BLK1. The number of rows along the Y-direction of the first channel structures CH constituting the second memory block BLK2 may be less than the number of rows in the Y-direction of the first channel structures CH constituting the first memory block BLK1.

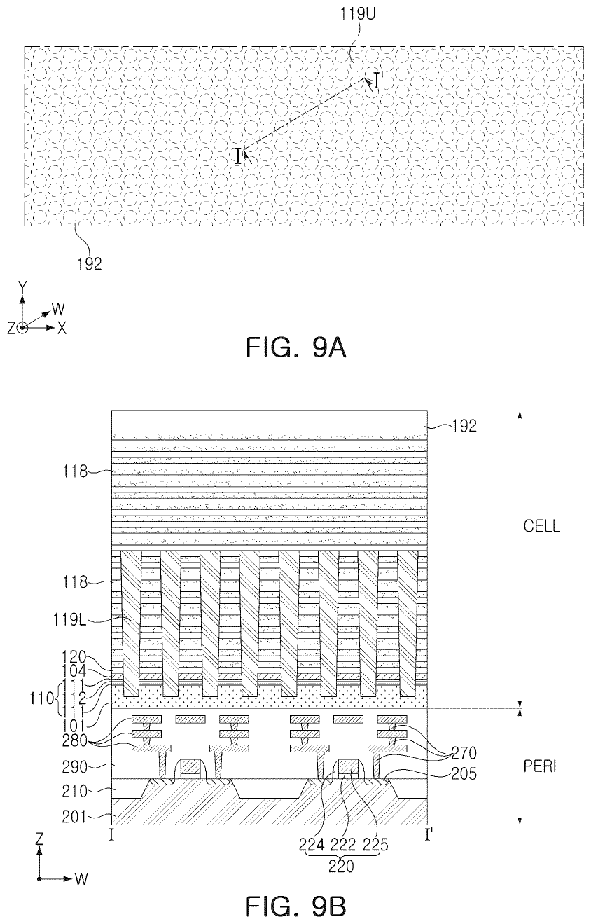

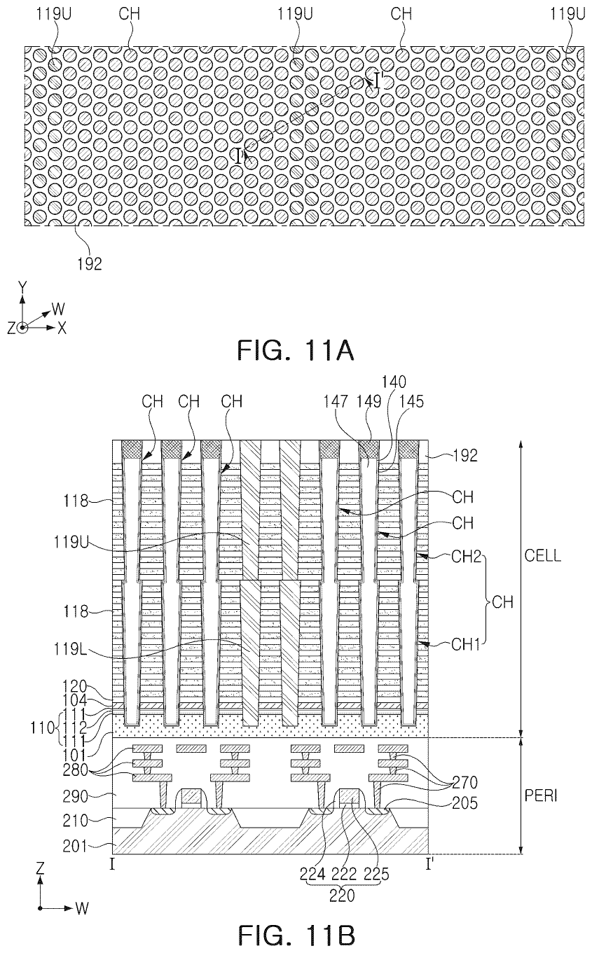

In some implementations, the width L1 of the first separation regions MS is constant, and distances L2 and L3 between the first separation regions MS may be different in the plurality of areas. Since the first separation regions MS are formed using vertical sacrificial layers 119L and 119U (see FIGS. 11A and 11B) formed together with the channel structures CH, the positions in which the first separation regions MS are formed may be easily adjusted, as described below with reference to FIGS. 9 to 15.

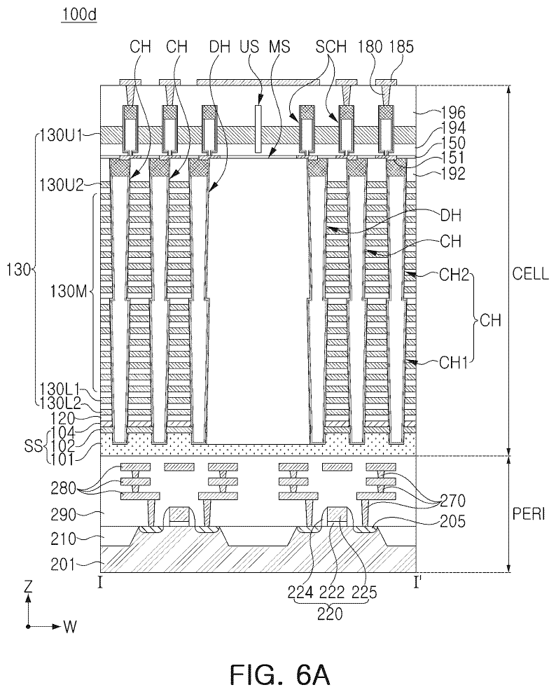

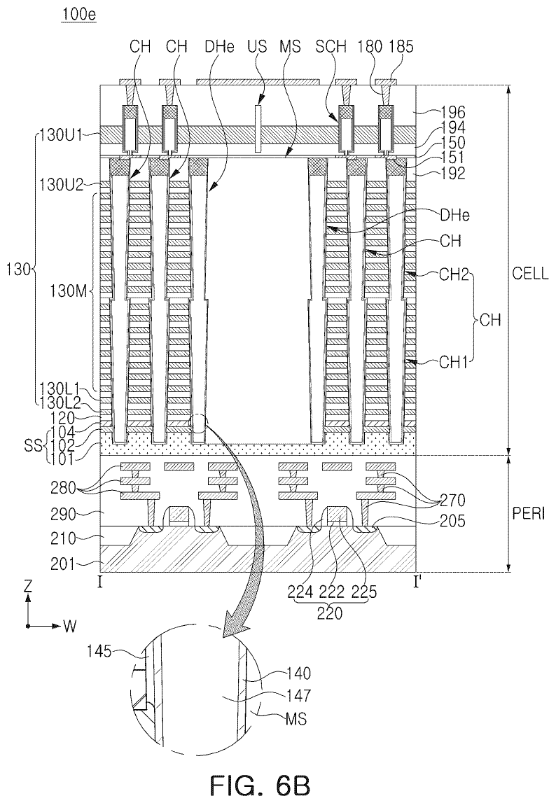

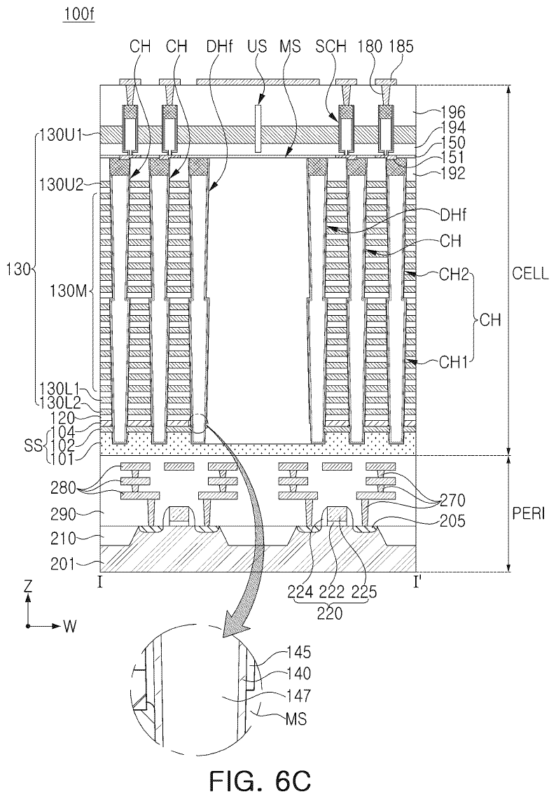

FIGS. 6A to 6C are schematic cross-sectional views of an exemplary semiconductor device according to some implementations and illustrate areas corresponding to FIG. 2. In FIG. 6A, in the semiconductor device 100d, second channel structures SCH may be further disposed on the dummy structures DH. However, the second channel structures SCH on the dummy structures DH may not be connected to the studs 180. Accordingly, the second channel structures SCH on the dummy structures DH may also be dummy structures.

In FIG. 6B, in the semiconductor device 100e, the dummy structures DHe may have a different structure from the first channel structures CH1. In the area in which the dummy structure DHe contacts the first isolation region MS, the first gate dielectric layer 145 disposed at the outermost part may be removed. Accordingly, the first gate dielectric layer 145 of the dummy structure DHe may have a shape corresponding to a portion of the first gate dielectric layer 145 of the first channel structures CH. However, the first channel layer 140 of the dummy structure DHe may have a shape corresponding to the first channel layer 140 of the first channel structure CH. In some implementations, the dummy structures DHe may have a cylindrical shape smaller than the first channel structures CH1.

In some implementations, in the dummy structure DHe, the first gate dielectric layer 145 may have only portions of the plurality of layers forming the first gate dielectric layer 145, for example, the blocking layer described above, removed.

In FIG. 6C, in the semiconductor device 100f, the dummy structures DHf may have a different structure from the first channel structures CH1. In the lower region of the region in contact with the first isolation region MS of the dummy structure DHf, the first gate dielectric layer 145 disposed at the outermost portion may be partially removed. For example, the first gate dielectric layer 145 may be partially removed at a level lower than the lowermost second lower gate electrode 130L2, for example, at a level lower than the upper surface of the second horizontal conductive layer 104. However, the first channel layer 140 of the dummy structure DHf may have a shape corresponding to the first channel layer 140 of the first channel structure CH1. In some implementations, the area from which the first gate dielectric layer 145 of the dummy structures DHf is removed may be changed in various manners, and the removed thickness may also be varied.

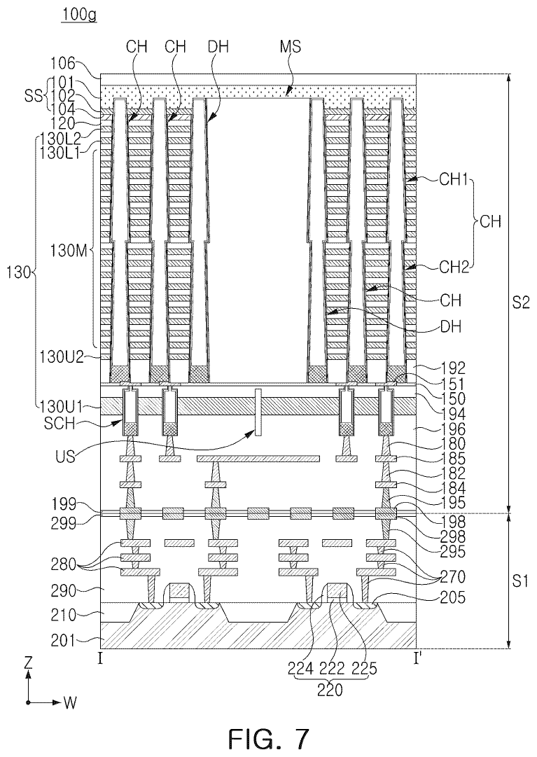

FIG. 7 is a schematic cross-sectional view of an exemplary semiconductor device according to some implementations. In FIG. 7, the semiconductor device 100g may include a first semiconductor structure S1 and a second semiconductor structure S2 bonded using a wafer bonding method.

The description of the peripheral circuit area PERI described above with reference to FIGS. 1 and 2 may be applied to the first semiconductor structure S1. However, the first semiconductor structure S1 may further include first bonding vias 295, first bonding metal layers 298, and first bonding insulating layer 299, which are bonding structures. The first bonding vias 295 may be disposed on upper portions of the uppermost circuit interconnection lines 280 and connected to the circuit interconnection lines 280. At least a portion of the first bonding metal layers 298 may be connected to the first bonding vias 295 on the first bonding vias 295. The first bonding metal layers 298 may be connected to the second bonding metal layers 198 of the second semiconductor structure S2. The bonding metal layers 298, together with the second bonding metal layers 198, may provide an electrical connection path for bonding the first semiconductor structure S1 and the second semiconductor structure S2.

Portions of the first bonding metal layers 298 may not be connected to the lower circuit interconnection lines 280 and may be disposed only for bonding. The first bonding vias 295 and the first bonding metal layers 298 may include a conductive material, for example, copper (Cu). The first bonding insulating layer 299 may be disposed around the first bonding metal layers 298. The first bonding insulating layer 299 may also function as a diffusion barrier of the first bonding metal layers 298 and may include, for example, at least one of SiN, SiON, SiCN, SiOC, SiOCN, and SiO.

For the second semiconductor structure S2, unless otherwise specified, the description of the memory cell region CELL described above with reference to FIGS. 1 to 3B may be applied. The second semiconductor structure S2 may further include lower contact plugs 182 and cell interconnection lines 184, which are cell interconnection structures, and may further include second bonding vias 195, second bonding metal layers 198, and second bonding insulating layers 199, which are bonding structures. The second semiconductor structure S2 may further include a passivation layer 106 covering the upper surface of the plate layer 101.

The lower contact plugs 182 may be connected to the bit lines 185, and the cell interconnection lines 184 may be connected to the lower contact plugs 182. However, in example embodiments, the number of layers and arrangement forms of contact plugs and interconnection lines forming the cell interconnection structure may vary. The lower contact plugs 182 and cell interconnection lines 184 may be formed of a conductive material and may include, for example, at least one of tungsten (W), aluminum (Al), and copper (Cu).

The second bonding vias 195 and second bonding metal layers 198 may be disposed below the lowermost cell interconnection lines 184. The second bonding vias 195 connect the cell interconnection lines 184 and the second bonding metal layers 198, and the second bonding metal layers 198 may be bonded to the first bonding metal layers 298 of the first semiconductor structure S1. The second bonding insulating layer 199 may be connected to the first bonding insulating layer 299 of the first semiconductor structure S1 by bonding. The second bonding vias 195 and the second bonding metal layers 198 may include a conductive material, for example, copper (Cu). The second bonding insulating layer 199 may include, for example, at least one of SiO, SiN, SiCN, SiOC, SiON, and SiOCN.

The first and second semiconductor structures S1 and S2 may be bonded by bonding the first bonding metal layers 298 and the second bonding metal layers 198 and bonding the first bonding insulating layer 299 and the second bonding insulating layer 199. The bonding of the first bonding metal layers 298 and the second bonding metal layers 198 may be, for example, copper (Cu)-to-copper (Cu) bonding, and the bonding of the first bonding insulating layer 299 and the second bonding insulating layer 199 may be, for example, dielectric-dielectric bonding such as SiCN-to-SiCN bonding. The first and second semiconductor structures S1 and S2 may be bonded by hybrid bonding including copper (Cu)-to-copper (Cu) bonding and dielectric-to-dielectric bonding.

The passivation layer 106 may be disposed on the upper surface of the plate layer 101 and may protect the semiconductor device 100g. The passivation layer 106 may include at least one of an insulating material, for example, silicon oxide, silicon nitride, and silicon carbide, and may be formed of a plurality of insulating layers in some implementations.

In some implementations, the second semiconductor structure S2 may not include the first and second horizontal conductive layers 102 and 104 (see FIG. 2). The first channel structures CH may be directly connected to the plate layer 101 in the state in which the first channel layers 140 (see FIG. 3B) are exposed through an upper end thereof. However, the electrical connection form of the first channel structures CH and the common source line may be changed in some implementations, and may also be possible for the first channel structures CH and source structures SS to have the same structure as the example embodiment of FIG. 2.

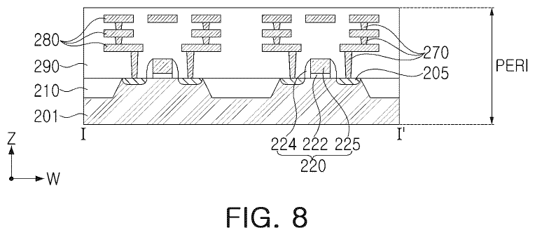

FIGS. 8 to 17 are schematic cross-sectional views illustrating an exemplary method of manufacturing a semiconductor device according to some implementations. FIGS. 8, 9B, 10B, 11B, 12B, 13B, 14B, 15B, 16, and 17 respectively illustrate areas corresponding to FIG. 2, and FIGS. 9A, 10A, 11A, 12A, 13A, 14A, and 15A respectively illustrate areas corresponding to FIG. 1.

In FIG. 8, circuit elements 220 forming a peripheral circuit area (PERI), a circuit interconnection structure, and a peripheral region insulating layer 290 may be formed on the substrate 201. First, the device isolation layers 210 are formed in the substrate 201, and the circuit gate dielectric layer 222 and the circuit gate electrode 225 may be sequentially formed on the substrate 201. The device isolation layers 210 may be formed by, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but is not limited thereto. Next, a spacer layer 224 and impurity regions 205 may be formed on both sidewalls of the circuit gate dielectric layer 222 and the circuit gate electrode 225. In some implementations, the spacer layer 224 may be composed of multiple layers. The impurity regions 205 may be formed by performing an ion implantation process.

Among the circuit interconnection structures, the circuit contact plugs 270 may be formed by forming a portion of the peripheral area insulating layer 290 and then partially etching and removing, and filling with a conductive material. The circuit interconnection lines 280 may be formed, for example, by depositing and then patterning a conductive material.

The peripheral area insulating layer 290 may be composed of a plurality of insulating layers. The peripheral area insulating layer 290 may be part of each step of forming the circuit interconnection structure. As a result, a peripheral circuit area PERI may be formed.

In FIGS. 9A and 9B, on the peripheral circuit area PERI, a plate layer 101 provided with a memory cell region CELL, a horizontal sacrificial layer 110, and a second horizontal conductive layer 104 may be formed, sacrificial insulating layers 118 and interlayer insulating layers 120 are alternately stacked to form a lower mold structure, and after forming the lower vertical sacrificial layers 119L, the upper mold structure may be formed. The plate layer 101 may be formed on the peripheral area insulating layer 290. The plate layer 101 may be made of, for example, polycrystalline silicon and may be formed through a CVD process. Polycrystalline silicon forming the plate layer 101 may contain impurities.

The first and second horizontal insulating layers 111 and 112 forming the horizontal sacrificial layer 110 may be alternately stacked on the plate layer 101. The horizontal sacrificial layer 110 may be layers that are replaced with the first horizontal conductive layer 102 of FIG. 2 through a subsequent process. In some implementations, the first horizontal insulating layers 111 may include a material different from that of the second horizontal insulating layer 112. For example, the first horizontal insulating layers 111 are formed of the same material as the interlayer insulating layers 120, and the second horizontal insulating layer 112 may be formed of the same material as the sacrificial insulating layers 118. The second horizontal conductive layer 104 may be formed on the horizontal sacrificial layer 110. Additionally, the lower mold structure may be formed on the second horizontal conductive layer 104 at a height at which the lower channel structures CH1 (see FIG. 2) of the first channel structures CH (see FIG. 2) are disposed.

The sacrificial insulating layers 118 may be a layer that is replaced as part of the gate electrodes 130 (see FIG. 2) through a subsequent process. The sacrificial insulating layers 118 may be formed of a material different from the interlayer insulating layers 120, and the interlayer insulating layers 120 may be formed of a material that may be etched with etch selectivity under specific etching conditions. For example, the interlayer insulating layer 120 may be formed of at least one of silicon oxide and silicon nitride, and the sacrificial insulating layers 118 may be formed of a material different from the interlayer insulating layer 120 selected from silicon, silicon oxide, silicon carbide, and silicon nitride. In some implementations, the thicknesses of the interlayer insulating layers 120 may not all be the same. The thickness of the interlayer insulating layers 120 and the sacrificial insulating layers 118 and the number of constituting films may vary from those shown.

The lower vertical sacrificial layers 119L may be formed at positions corresponding to the lower channel structures CH1. The lower vertical sacrificial layers 119L may be further formed in regions corresponding to lower regions of the dummy structures DH and portions of the first separation regions MS of FIG. 2. In FIG. 9A, the lower vertical sacrificial layers 119L may be arranged regularly throughout the area in which the first channel structures CH1, the dummy structures DH, and the first separation regions MS are to be disposed. The lower vertical sacrificial layers 119L may be formed after forming holes to penetrate the lower mold structure, depositing a material forming lower vertical sacrificial layers 119L in the holes and performing a planarization process. The lower vertical sacrificial layers 119L may include, for example, carbon (C), but are not limited thereto.

The upper mold structure may be formed on the lower mold structure at a height where the upper channel structures CH2 (see FIG. 2) of the first channel structures CH are disposed. The upper mold structure may be formed by alternately stacking sacrificial insulating layers 118 and lower interlayer insulating layers 120 in the same manner as the lower mold structure. A first cell region insulating layer 192 may be formed on the uppermost sacrificial insulating layers 118.

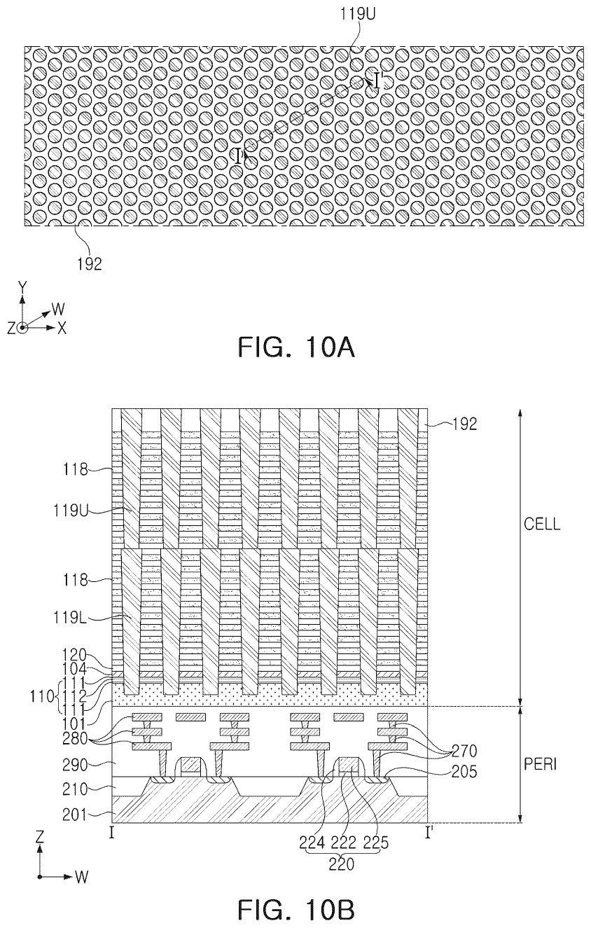

In FIGS. 10A and 10B, upper vertical sacrificial layers 119U may be formed penetrating through the upper mold structure. The upper vertical sacrificial layers 119U may be formed on the lower vertical sacrificial layers 119L, respectively. The upper vertical sacrificial layers 119U may be respectively connected to the lower vertical sacrificial layers 119L. The upper vertical sacrificial layers 119U may include the same material as the lower vertical sacrificial layers 119L. The upper vertical sacrificial layers 119U may include, for example, carbon (C), but are not limited thereto.

In FIGS. 11A and 11B, first channel structures CH may be formed. First, first channel holes may be formed by removing portions of the lower vertical sacrificial layers 119L and upper vertical sacrificial layers 119U. For example, when the lower vertical sacrificial layers 119L and upper vertical sacrificial layers 119U include carbon (C), portions of the lower vertical sacrificial layers 119L and upper vertical sacrificial layers 119U may be removed by an ashing process.

In the area corresponding to the positions of the first separation regions MS of FIG. 2, the lower vertical sacrificial layers 119L and the upper vertical sacrificial layers 119U may remain without being removed. For example, as shown in FIG. 11A, two rows of lower vertical sacrificial layers 119L and upper vertical sacrificial layers 119U may remain at predetermined intervals in the Y-direction. However, the number and spacing of rows of the remaining lower vertical sacrificial layers 119L and upper vertical sacrificial layers 119U may be selected in various manners in some implementations.

The first channel structures CH may be formed by sequentially depositing at least a portion of the first gate dielectric layer 145, the first channel layer 140, the first channel buried insulating layer 147, and the first channel pad 149 in the first channel holes. The first gate dielectric layer 145 may be formed to have a uniform thickness using an ALD or CVD process. In some implementations, the first gate dielectric layer 145 may be formed in whole or in part, and a portion extending perpendicular to the plate layer 101 along the first channel structures CH may be formed in this operation. The first channel layer 140 may be formed on the first gate dielectric layer 145 within the lower channel holes. The first channel buried insulating layer 147 is formed to fill the lower channel holes and may be formed of an insulating material. The first channel pad 149 may be formed after partially removing the first channel buried insulating layer 147. The first channel pad 149 may be formed of a conductive material, for example, polycrystalline silicon. In some implementations, the first channel structures CH are formed using portions of the lower vertical sacrificial layers 119L and upper vertical sacrificial layers 119U that are arranged regularly over the entire area, and may be formed into a uniform size.

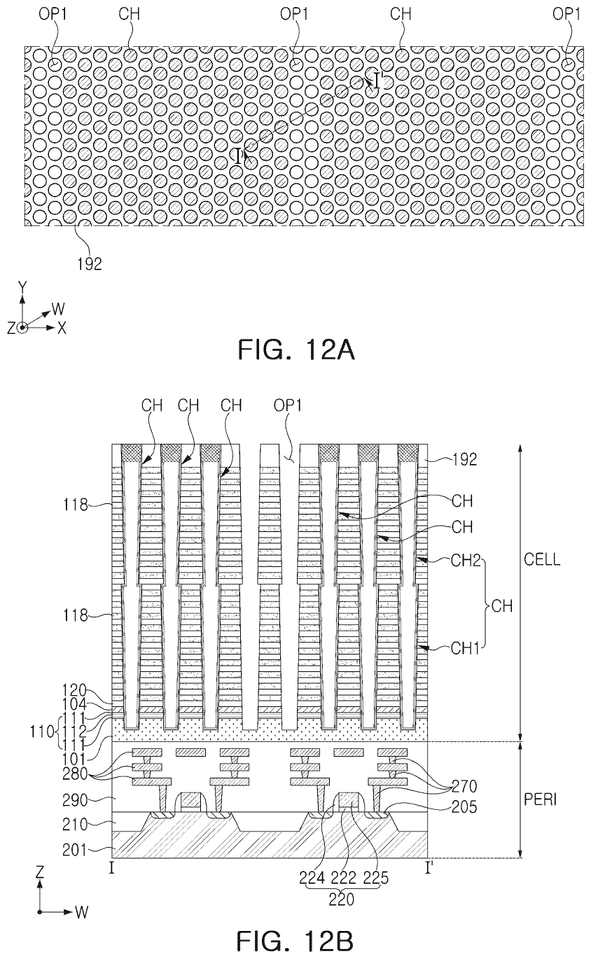

In FIGS. 12A and 12B, the lower vertical sacrificial layers 119L and the upper vertical sacrificial layers 119U may be removed to form first openings OP1. The first openings OP1 may be formed by removing the remaining lower vertical sacrificial layers 119L and upper vertical sacrificial layers 119U. The lower vertical sacrificial layers 119L and upper vertical sacrificial layers 119U may be removed by, for example, an ashing process.

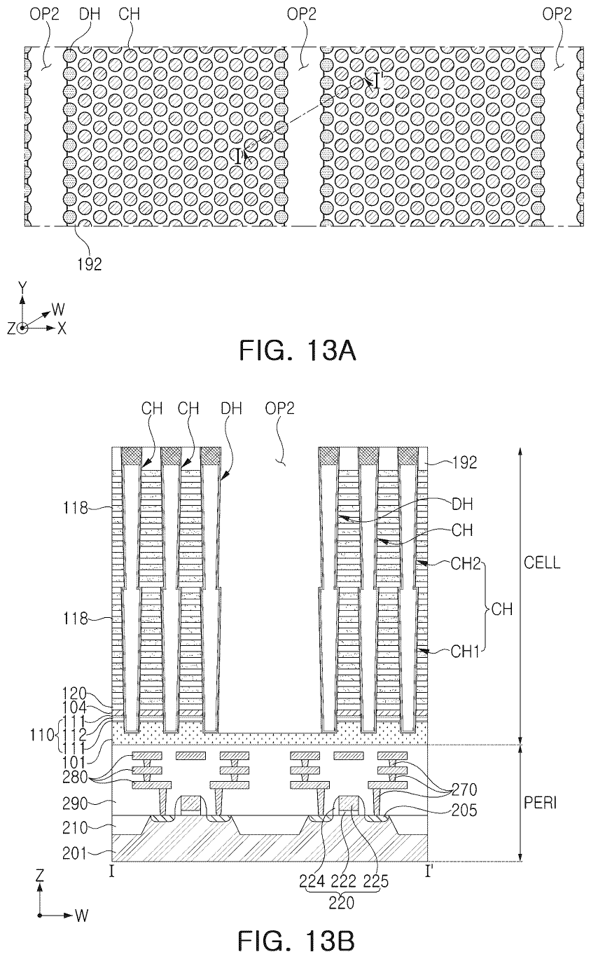

In FIGS. 13A and 13B, the first openings OP1 may be enlarged to form second openings OP2. The second openings OP2 may be formed by connecting adjacent first openings OP1 to each other by enlarging the size of the first openings OP1. The second openings OP2 may be formed, for example, by partially removing the stack structure of the interlayer insulating layers 120 and sacrificial insulating layers 118 exposed by the first openings OP1 using a wet etching process. Each of the first openings OP1 may be enlarged to a length by which adjacent first openings OP1 may be connected to each other, or more. For example, each of the first openings OP1 may be enlarged to a range of about 30 nm to about 60 nm on one side.

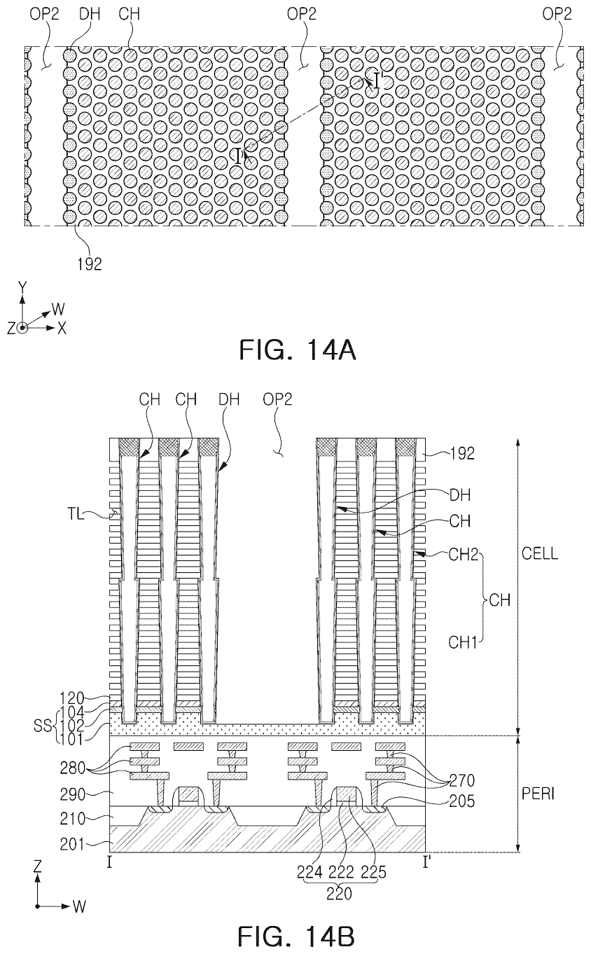

At least portions of the first channel structures CH1 may be exposed through the second openings OP2, and may result in support structures DH. Portions of each side surface of the support structures DH are exposed through the second openings OP2, and other portions may contact the stack structure of interlayer insulating layers 120 and sacrificial insulating layers 118. In FIGS. 6B and 6C, a portion of the first gate dielectric layer 145 may be removed and formed in this operation and/or in the subsequent process steps described with reference to FIGS. 14A and 14B.

In FIGS. 14A and 14B, the first horizontal conductive layer 102 may be formed and the sacrificial insulating layers 118 may be removed. First, an etch-back process is performed while forming separate sacrificial spacer layers in the second openings OP2 to selectively remove the horizontal sacrificial layer 110, and a portion of the exposed first gate dielectric layer 145 (see FIG. 3B) may also be removed. After forming the first horizontal conductive layer 102 by depositing a conductive material in the area in which the horizontal sacrificial layer 110 was removed, the sacrificial spacer layers may be removed within the second openings OP2.

The sacrificial insulating layers 118 may be removed selectively with respect to the interlayer insulating layers 120, the second horizontal conductive layer 104, and the first channel structures CH, using, for example, wet etching. Tunnel portions TL may be formed in areas in which the sacrificial insulating layers 118 have been removed.

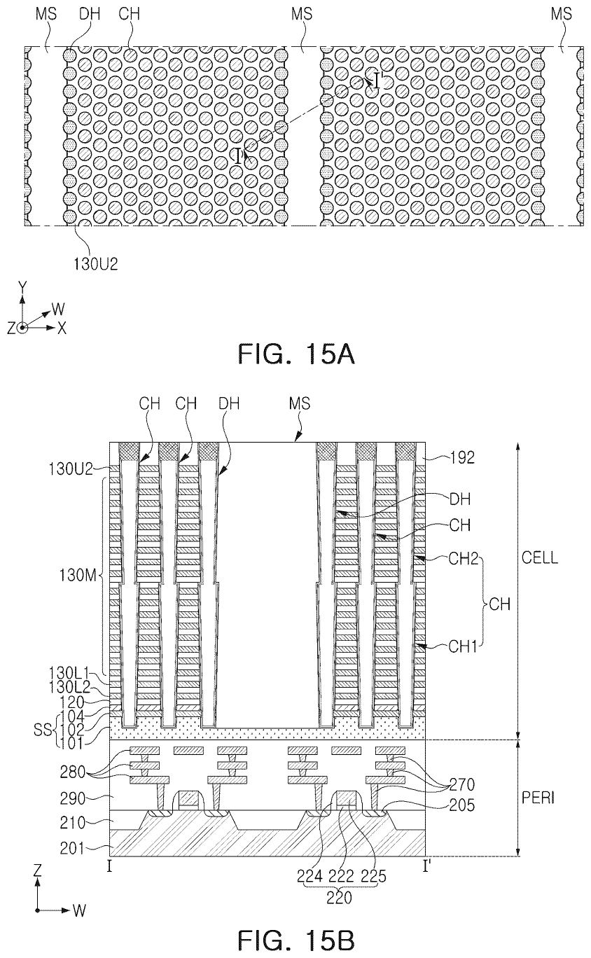

In FIGS. 15A and 15B, a second lower gate electrode 130L2, a first lower gate electrode 130L1, memory gate electrodes 130M, and a second upper gate electrode 130U2 are formed, and first separation regions MS may be formed. Among the gate electrodes 130, first gate electrodes surrounding the first channel structures CH, for example, the second lower gate electrode 130L2, the first lower gate electrode 130L1, the memory gate electrodes 130M, and a second upper gate electrode 130U2 may be formed. The first gate electrodes may be formed by depositing a conductive material on the tunnel portions TL. In some implementations, a portion of the first gate dielectric layer 145 may be formed first before forming the first gate electrodes. After forming the first gate electrodes, the first isolation region MS may be formed by depositing an insulating material in the second openings OP2.

The first separation regions MS are formed using portions of the lower vertical sacrificial layers 119L and the upper vertical sacrificial layers 119U, and the formation position within the semiconductor device may be easily adjusted. Additionally, since the first separation regions MS does not affect the shape of the first channel structures CH1, the difficulty in designing the semiconductor device may be reduced.

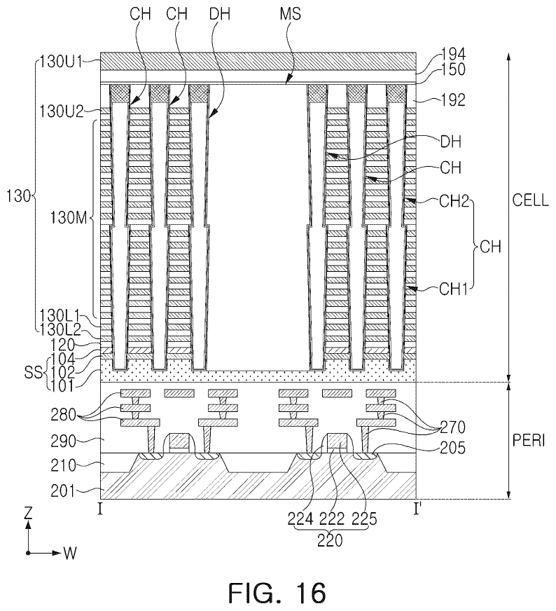

In FIG. 16, the horizontal insulating layer 150 and the second cell region insulating layer 194 may be formed, and the first upper gate electrode 130U1 may be formed. The horizontal insulating layer 150 may be formed to cover the upper surfaces of the first channel structures CH, the upper surfaces of the dummy structures DH, and the upper surfaces of the first separation regions MS. Next, the second cell region insulating layer 194 and the first upper gate electrode 130U1 may be formed sequentially. The first upper gate electrode 130U1 may be formed through a deposition process and a patterning process. For example, the first upper gate electrode 130U1 may include polycrystalline silicon.

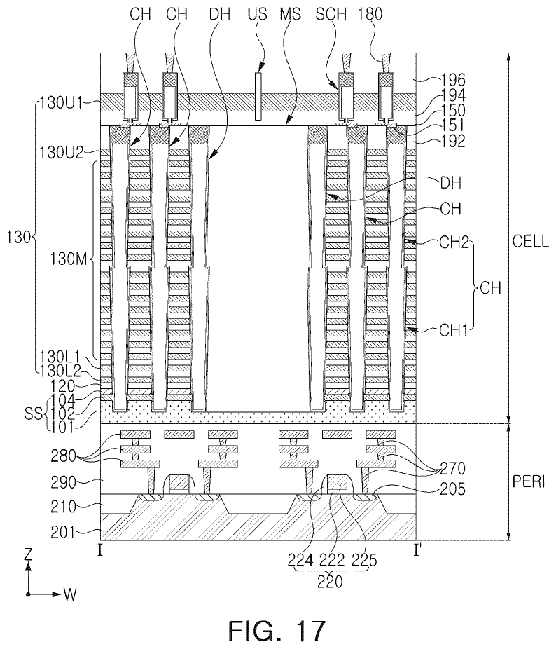

In FIG. 17, second channel structures SCH penetrating through the first upper gate electrode 130U1 may be formed, and studs 180 may be formed. First, the third cell region insulating layer 196 may be formed on the first upper gate electrode 130U1.

The second channel structures SCH may be formed to respectively correspond to the first channel structures CH1. First, after forming second channel holes penetrating through the first upper gate electrode 130U1, second channel dielectric layers 165 (see FIG. 3A) and sacrificial layers may be formed sequentially. Then, lower holes are formed in the bottom surfaces of the second channel holes and extend through the second channel dielectric layers 165 and the sacrificial layers to the horizontal insulating layer 150, and the first channel pads 149 (see FIG. 3A) may be exposed by partially removing the horizontal insulating layer 150 exposed through the lower holes. After forming connection pads 151 in areas in which the horizontal insulating layer 150 was removed and removing the sacrificial layers, a second channel layer 160, a second channel buried layer 167, and a second channel pad 169 are sequentially formed as illustrated in FIG. 3A in the respective upper channel holes, and thus, the second channel structures SCH may be formed. Each layer may be formed in the same manner as in the first channel structures CH. Lower portions of the second channel layers 160 may be connected to the connection pads 151.

The studs 180 may each be formed on the second channel structures SCH. Next, referring to FIG. 2, the semiconductor device 100 may be manufactured by forming bit lines 185 on the studs 180.

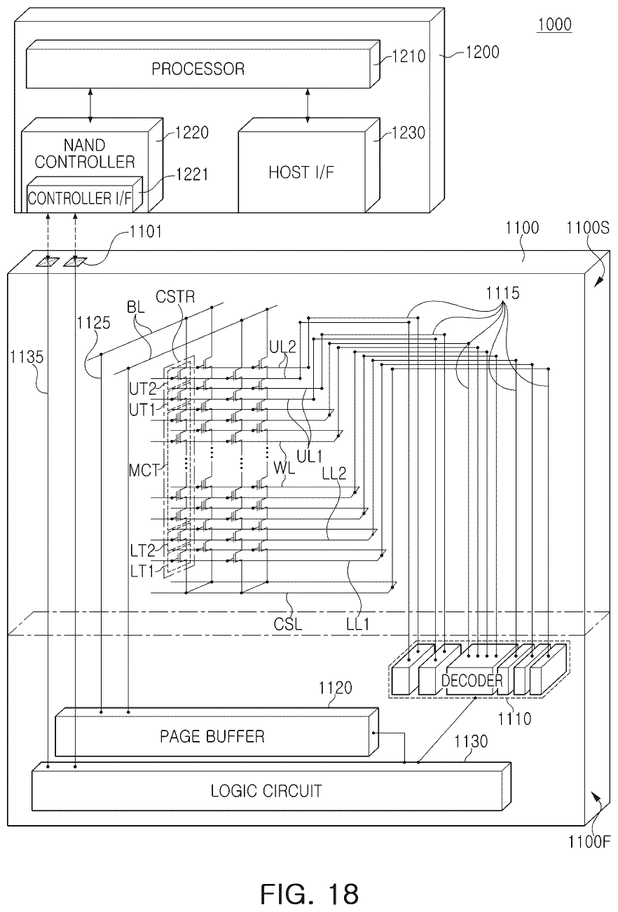

FIG. 18 is a diagram schematically illustrating an exemplary data storage system including a semiconductor device according to some implementations. In FIG. 18, the data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, the data storage system 1000 may be a solid state drive device (SSD) device, a universal serial bus (USB) device, a computing system, a medical device, or a communication device including one or a plurality of semiconductor devices 1100.

The semiconductor device 1100 may be a non-volatile memory device, for example, the NAND flash memory device described above with reference to FIGS. 1 to 7. The semiconductor device 1100 may include a first structure 1100F and a second structure 1100S on the first structure 1100F. In some implementations, the first structure 1100F may be placed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR includes lower transistors LT1 and LT2 adjacent to the common source line CSL, upper transistors UT1 and UT2 adjacent to the bit line BL, and lower transistors LT1 and LT2 and a plurality of memory cell transistors (MCT) disposed between the upper transistors UT1 and UT2. The number of lower transistors LT1 and LT2 and the number of upper transistors UT1 and UT2 may vary depending on embodiments.

In some implementations, the upper transistors UT1 and UT2 may include string select transistors, and the lower transistors LT1 and LT2 may include a ground selection transistor. The gate lower lines LL1 and LL2 may be gate electrodes of the lower transistors LT1 and LT2, respectively. The word lines (WL) may be gate electrodes of memory cell transistors (MCT), and the gate upper lines UL1 and UL2 may be gate electrodes of the upper transistors UT1 and UT2, respectively.

In some implementations, the lower transistors LT1 and LT2 may include a lower erase control transistor LT1 and a ground selection transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used in an erase operation to erase data stored in the memory cell transistors MCT using the GIDL phenomenon.

The common source line (CSL), the first and second gate lower lines (LL1 and LL2), the word lines (WL), and the first and second gate upper lines (UL1 and UL2) may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 1100F to the second structure 1100S.

In the first structure 1100F, the decoder circuit 1110 and the page buffer 1120 may perform a control operation on at least one selected memory cell transistor among the plurality of memory cell transistors (MCT). The decoder circuit 1110 and page buffer 1120 may be controlled by the logic circuit 1130. The semiconductor device 1100 may communicate with the controller 1200 through the input/output pad 1101 that is electrically connected to the logic circuit 1130. The input/output pad 1101 may be electrically connected to the logic circuit 1130 through an input/output connection interconnection 1135 extending from the first structure 1100F to the second structure 1100S.

The controller 1200 may include a processor 1210, a NAND controller 1220, and a host interface 1230. In some implementations, the data storage system 1000 may include a plurality of semiconductor devices 1100, and in this case, the controller 1200 may control a plurality of semiconductor devices 1100.

The processor 1210 may control the overall operation of the data storage system 1000, including the controller 1200. The processor 1210 may operate according to predetermined firmware and may control the NAND controller 1220 to access the semiconductor device 1100. The NAND controller 1220 may include a controller interface 1221 that processes communication with the semiconductor device 1100. Via the controller interface 1221, control commands for controlling the semiconductor device 1100, data to be written to the memory cell transistors (MCT) of the semiconductor device 1100, and data to be read from the memory cell transistors (MCT) of the semiconductor device 1100, and the like may be transmitted. The host interface 1230 may provide a communication function between the data storage system 1000 and an external host. When receiving a control command from an external host through the host interface 1230, the processor 1210 may control the semiconductor device 1100 in response to control commands.

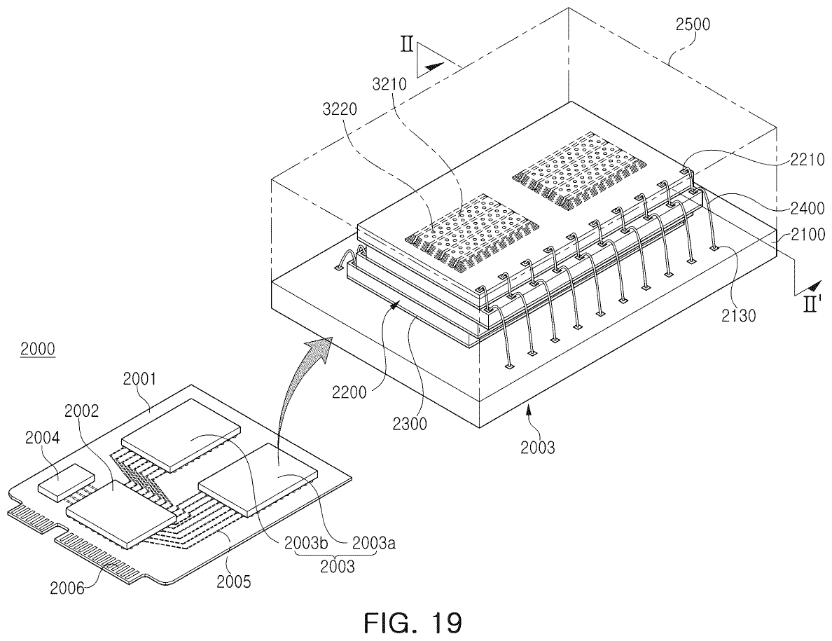

FIG. 19 is a perspective view schematically illustrating an exemplary data storage system including a semiconductor device according to some implementations. In FIG. 19, a data storage system 2000 includes a main board 2001, a controller 2002 mounted on the main board 2001, one or more semiconductor packages 2003, and DRAM 2004. The semiconductor package 2003 and the DRAM 2004 may be connected to the controller 2002 through interconnection patterns 2005 formed on the main board 2001. The main board 2001 may include a connector 2006 including a plurality of pins coupled to an external host. The number and arrangement of the plurality of pins in the connector 2006 may vary depending on the communication interface between the data storage system 2000 and the external host. In some implementations, the data storage system 2000 may communicate with an external host through any one of the following interfaces: Universal Serial Bus (USB), Peripheral Component Interconnect Express (PCI-Express), Serial Advanced Technology Attachment (SATA), and M-Phy for Universal Flash Storage (UFS). In some implementations, the data storage system 2000 may operate with power supplied from an external host through the connector 2006. The data storage system 2000 may further include a Power Management Integrated Circuit (PMIC) that distributes power supplied from the external host to the controller 2002 and the semiconductor package 2003.

The controller 2002 may write data to the semiconductor package 2003 or read data from the semiconductor package 2003, and may improve the operation speed of the data storage system 2000. The DRAM 2004 may be a buffer memory to alleviate the speed difference between the semiconductor package 2003, which is a data storage space, and an external host. The DRAM 2004 included in the data storage system 2000 may also operate as a type of cache memory. A space for temporarily storing data may be provided during control operations for the semiconductor package 2003. When the data storage system (2000) includes DRAM (2004), the controller 2002 may further include a DRAM controller for controlling the DRAM 2004 in addition to a NAND controller for controlling the semiconductor package 2003.

The semiconductor package 2003 may include first and second semiconductor packages 2003a and 2003b that are spaced apart from each other. The first and second semiconductor packages 2003a and 2003b may each include a plurality of semiconductor chips 2200. Each of the first and second semiconductor packages 2003a and 2003b may include a package substrate 2100, semiconductor chips 2200 on a package substrate 2100, adhesive layers 2300 disposed on the lower surface of each semiconductor chip 2200, a connection structure 2400 that electrically connects the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each semiconductor chip 2200 may include an input/output pad 2210. The input/output pad 2210 may correspond to the input/output pad 1101 of FIG. 18. Each of the semiconductor chips 2200 may include gate stack structures 3210 and channel structures 3220. Each of the semiconductor chips 2200 may include the semiconductor device described above with reference to FIGS. 1 to 7.

In some implementations, the connection structure 2400 may be a bonding wire that electrically connects the input/output pad 2210 and the upper pads 2130 of the package. Accordingly, in each of the first and second semiconductor packages 2003a and 2003b, the semiconductor chips 2200 may be electrically connected to each other using a bonding wire method, and may be electrically connected to the package upper pads 2130 of the package substrate 2100. According to some implementations, in each of the first and second semiconductor packages 2003a and 2003b, instead of the bonding wire-type connection structure 2400, the semiconductor chips 2200 may be electrically connected to each other by a connection structure including a through electrode (Through Silicon Via, TSV).

In some implementations, the controller 2002 and the semiconductor chips 2200 may be included in one package. For example, the controller 2002 and the semiconductor chips 2200 are mounted on a separate interposer board different from the main board 2001, and the controller 2002 and the semiconductor chips 2200 may be connected to each other through-wiring formed on the interposer substrate.

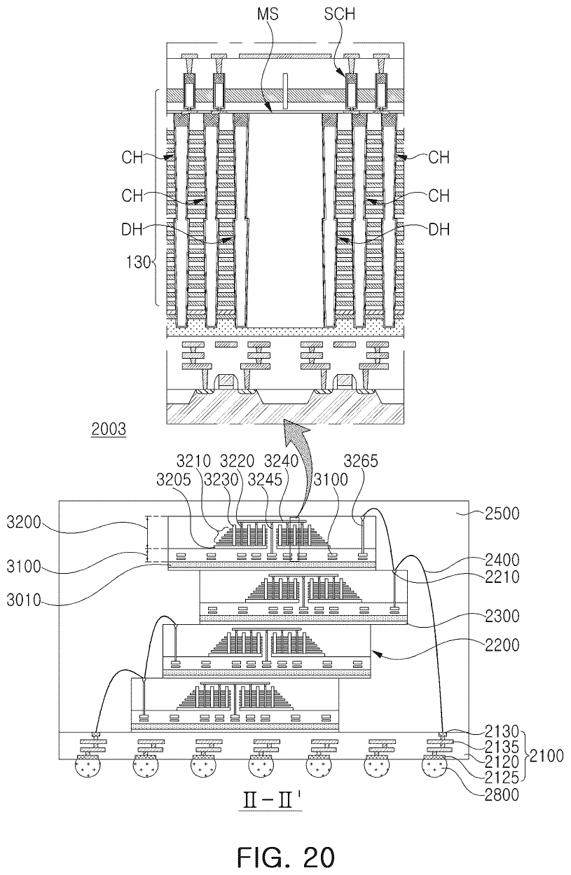

FIG. 20 is a cross-sectional view along line II-II′ of FIG. 19 schematically illustrating an exemplary semiconductor package according to some implementations. In FIG. 20, in the semiconductor package 2003, the package substrate 2100 may be a printed circuit board. The package substrate 2100 may include a package substrate body portion 2120, package upper pads 2130 disposed on the upper surface of the package substrate body 2120, lower pads 2125 disposed on or exposed through the lower surface of the package substrate body 2120, and internal interconnections 2135 electrically connecting the upper pads 2130 and the lower pads 2125 inside the package substrate body 2120. The lower pads 2125 may be connected to the interconnection patterns 2005 of the main board 2001 of the data storage system 2000, as illustrated in FIG. 19, through conductive connectors 2800.

Each of the semiconductor chips 2200 may include a semiconductor substrate 3010 and a first structure 3100 and a second structure 3200 that are sequentially stacked on the semiconductor substrate 3010. The first structure 3100 may include a peripheral circuit area including peripheral interconnections 3110. The second structure 3200 may include a common source line 3205, a gate stack structure 3210 on common source line 3205, channel structures 3220 penetrating through the gate stack structure 3210, bit lines 3240 electrically connected to the channel structures 3220, and contact plugs 3235 electrically connected to the word lines WL (see FIG. 18) of the gate stack structure 3210. As described above with reference to FIGS. 1 to 7, the first separation region MS in each of the semiconductor chips 2200 may be in contact with dummy structures DH having the same or similar structure as the first channel structures CH.

Each of the semiconductor chips 2200 may include a through-wiring 3245 that is electrically connected to the peripheral interconnections 3110 of the first structure 3100 and extends into the second structure 3200. The through-wiring 3245 may be disposed outside the gate stack structure 3210 and may be further disposed to penetrate the gate stack structure 3210. Each of the semiconductor chips 2200 may further include an input/output pad 2210 (see FIG. 19) that is electrically connected to the peripheral interconnections 3110 of the first structure 3100.

As set forth above, by including first separation regions formed using channel holes, a semiconductor device having improved design freedom and reduced process difficulty and a data storage system including the same may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

What is claimed is:

1. A semiconductor device comprising:
a first semiconductor structure; and
a second semiconductor structure on the first semiconductor structure,
wherein the second semiconductor structure includes:
a plate layer;
a plurality of first gate electrodes that are stacked on the plate layer and are spaced apart from each other in a first direction, each first gate electrode of the plurality of first gate electrodes being perpendicular to an upper surface of the plate layer;
a plurality of separation regions that each extend into at least one first gate electrode of the plurality of first gate electrodes, extend in a second direction, and are perpendicular to the first direction;
a plurality of first channel structures that are each spaced apart from the plurality of separation regions in a third direction, that are perpendicular to the first direction and the second direction, that extend into at least one of the plurality of first gate electrodes, and that extend in the first direction; and
a plurality of dummy structures that each contact at least one of the plurality of separation regions, extend into at least one of the plurality of first gate electrodes and extend in the first direction,
wherein each first channel structure of the plurality of first channel structures and each dummy structure of the plurality of dummy structures respectively has a circular shape in a plan view, and
wherein each separation region of the plurality of separation regions is in contact with at least portions of respective side surfaces of at least one dummy structure of the plurality of dummy structures.

2. The semiconductor device of claim 1, wherein each first channel structure of the plurality of first channel structures and each dummy structure of the plurality of dummy structures include a gate dielectric layer, a data storage layer, and a channel layer that are sequentially disposed from each first gate electrode of the plurality of first gate electrodes.

3. The semiconductor device of claim 2, wherein a shape of the channel layer of each first channel structure of the plurality of first channel structures is substantially a same as a shape of the channel layer of each dummy structure of the plurality of dummy structures.

4. The semiconductor device of claim 2, wherein the gate dielectric layer of each dummy structure of the plurality of dummy structures has a shape corresponding to a portion of the gate dielectric layer of each first channel structure of the plurality of first channel structures.

5. The semiconductor device of claim 1,
wherein each first channel structure of the plurality of first channel structures and each dummy structure of the plurality of dummy structures is arranged in a row of a plurality of rows along the second direction, and
wherein each dummy structure of the plurality of dummy structures is arranged in at least one row of the plurality of rows on both sides of each separation region of the plurality of separation regions in the third direction, respectively.

6. The semiconductor device of claim 5, wherein a portion of each of side surfaces of each separation region of the plurality of separation regions in the third direction is positioned between each adjacent dummy structure of the plurality of dummy structures of the at least one row of the plurality of rows.

7. The semiconductor device of claim 1,
wherein a first portioof each separation region of the plurality of separation regions is spaced apart by a first length in the third direction, and
wherein a second portion of each separation region of the plurality of separation regions is spaced apart by a second length less than the first length in the third direction.

8. The semiconductor device of claim 1, wherein the second semiconductor structure further includes:
a second gate electrode on each first gate electrode of the plurality of first gate electrodes; and
a plurality of second channel structures that each extend into the second gate electrode and are respectively connected to at least one first channel structure of the plurality of first channel structures.

9. The semiconductor device of claim 8,
wherein the second semiconductor structure further includes a horizontal insulating layer between each first channel structure of the plurality of first channel structures and the second gate electrode, and
wherein each dummy structure of the plurality of dummy structures is separated from each second channel structure of the plurality of second channel structures and wherein each dummy structure of the plurality of dummy structures has an upper surface entirely covered with the horizontal insulating layer.

10. The semiconductor device of claim 1,
wherein the second semiconductor structure further includes a cell interconnection structure on each first channel structure of the plurality of first channel structures, the cell interconnection structure being electrically connected to at least one first channel structure of the plurality of first channel structures, and
wherein each dummy structure of the plurality of dummy structures is not electrically connected to the cell interconnection structure.

11. The semiconductor device of claim 1, wherein a width of each separation region of the plurality of separation regions in the third direction is greater than a pitch of each first channel structure of the plurality of first channel structures in the third direction.

12. The semiconductor device of claim 11, wherein the width ranges from about 400 nm to about 700 nm.

13. A semiconductor device comprising:
a plate layer;
a plurality of gate electrodes that are stacked on the plate layer and are spaced apart from each other in a first direction, each first gate electrode of the plurality of gate electrodes being perpendicular to an upper surface of the plate layer;
a plurality of channel structures that each extend into at least one gate electrode of the plurality of gate electrodes, that extend in the first direction, that are arranged in rows along a second direction perpendicular to the first direction;
a plurality of dummy structures that are each on outsides of at least one channel structure of the plurality of channel structures and extend in the first direction, each dummy structure of the plurality of dummy structures extends into at least one gate electrode of the plurality of gate electrodes and is arranged in a row of a plurality of rows along the second direction; and
a plurality of separation regions that are each between rows of the plurality of rows of the plurality of dummy structures and extend into at least one gate electrode of the plurality of gate electrodes, each separation region of the plurality of separation regions extends in the second direction,
wherein each channel structure of the plurality of channel structures is arranged at a first pitch in a third direction, and each channel structure of the plurality of channel structures is perpendicular to the first direction and the second direction, and
wherein a width of each separation region of the plurality of separation regions is greater than the first pitch.

14. The semiconductor device of claim 13, wherein each separation region of the plurality of separation regions is disposed at a second pitch in a first region and disposed at a third pitch less than the second pitch in a second region.

15. The semiconductor device of claim 14, wherein the second region includes a spare memory block.

16. The semiconductor device of claim 14, further comprising:
a plurality of studs that are on at least one channel structure of the plurality of channel structures and are electrically connected to the at least one channel structure of the plurality of channel structures in both the first region and the second region.

17. The semiconductor device of claim 13, wherein each separation region of the plurality of separation regions is in contact with at least one dummy structure of the plurality of dummy structures.

18. The semiconductor device of claim 13, wherein each separation region of the plurality of separation regions has curved side surfaces corresponding to portions of respective side surfaces of each dummy structure of the plurality of dummy structures.

19. A data storage system comprising:
a semiconductor storage device including a first semiconductor structure including circuit elements, a second semiconductor structure on one surface of the first semiconductor structure, and an input/output pad electrically connected to the circuit elements; and
a controller electrically connected to the semiconductor storage device through the input/output pad and configured to control the semiconductor storage device,
wherein the second semiconductor structure includes:
a plate layer;
a plurality of gate electrodes that are stacked on the plate layer, and are spaced apart from each other in a first direction, each gate electrode of the plurality of gate electrodes being perpendicular to an upper surface of the plate layer;
a plurality of channel structures that each extend in the first direction and extend into at least one gate electrode of the plurality of gate electrodes, each channel structure of the plurality of channel structures being arranged in one row of a plurality of rows along a second direction perpendicular to the first direction;
a plurality of dummy structures that are each on outsides of at least one channel structure of the plurality of channel structures and extend into the at least one gate electrode of the plurality of gate electrodes, each dummy structure of the plurality of dummy structures extends in the first direction, and is arranged in one row of the plurality of rows along the second direction; and
a plurality of separation regions that are each between the one row of the plurality of rows of the plurality of dummy structures and extend into the at least one gate electrode of the plurality of gate electrodes, each separation region of the plurality of separation regions extends in the second direction,
wherein each separation region of the plurality of separation regions surrounds at least a portion of each dummy structure of the plurality of dummy structures and is in contact with the plurality of dummy structures.

20. The data storage system of claim 19, wherein each channel structure of the plurality of channel structures and each dummy structure of the plurality of dummy structures respectively has a cylindrical shape.
